(19) United States
(12) Patent Application Publication
(10) Pub. No.: US 2025/0204045 A1
(43) Pub. Date: Jun. 19, 2025

(54) ARRAY SUBSTRATE AND DISPLAY PANEL

(71) Applicant: Guangzhou China Star Optoelectronics Semiconductor Display Technology Co., LTd., Guangzhou (CN)

(72) Inventors: Xin LIAO, Guangzhou (CN); Fen LONG, Guangzhou (CN)

(73) Assignee: Guangzhou China Star Optoelectronics Semiconductor Display Technology Co., LTd., Guangzhou (CN)

(21) Appl. No.: 18/985,013

(22) Filed: Dec. 17, 2024

(30) Foreign Application Priority Data
Dec. 18, 2023 (CN) 202311750137.4

(51) Int. Cl. H10D 86/40; H10D 86/60

(52) U.S. Cl. CPC H10D 86/441; H10D 86/60

(57) ABSTRACT

The present disclosure provides an array substrate and a display panel. The array substrate includes a pixel area and a driving area, and further includes a substrate layer, a first conductive layer, a first insulating layer, a second conductive layer, a second insulating layer, and a third conductive layer. The first conductive layer includes a first wiring segment, which is at least partially located in the pixel area. The second conductive layer includes a second wiring segment, which is at least partially located in the driving area. The first wiring segment and the second wiring segments are electrically connected. The conductive layer includes a common electrode located in the pixel area, and an orthographic projection of the common electrode on the substrate layer at least partially overlaps an orthogonal projection of the first wiring segment on the substrate layer.

### CROSS-REFERENCE TO RELATED APPLICATION

This application claims priority to Chinese Patent Application No. 202311750137.4, filed on Dec. 18, 2023, the disclosure of which is incorporated herein by reference in its entirety.

### TECHNICAL FIELD

This present disclosure relates to display technologies.

### BACKGROUND

In traditional methods of designing a display panel pixel, in order to prevent light leakage and color crosstalk, a layer of common electrode is typically covered over the metal data line as a light shielding electrode to shield the electric field on the data line. However, this design significantly increases the capacitance on the data line, that is, the parasitic capacitance of the pixel is significantly increased. Such increase in parasitic capacitance typically leads to a decrease in the pixel charging rate, and the larger parasitic capacitance also causes an increase in the coupling voltage between the data line and the common electrode, thereby increasing the risk of lateral crosstalk.

### SUMMARY

One or more embodiments of the present disclosure provide an array substrate, which includes a pixel area and a driving area. The array substrate further includes a substrate layer, a first conductive layer, a first insulating layer, a second conductive layer, a second insulating layer and a third conducive layer. The first conductive layer is disposed on the substrate layer, and the first conductive layer includes a first wiring segment, which is at least partially located in the pixel area. The first insulating layer is disposed on the first conductive layer. The second conductive layer is disposed on the first insulating layer, and the second conductive layer includes a second wiring segment, which is at least partially located in the driving area. The second wiring segment extends along a first direction, and is electrically connected to the first wiring segment. The second insulating layer is disposed on the second conductive layer. The third conductive layer is disposed on the second insulating layer, and includes a common electrode located in the pixel area. An extension direction of the common electrode is consistent with that of the first wiring segment, and an orthographic projection of the common electrode on the substrate layer at least partially overlaps an orthogonal projection of the first wiring segment on the substrate layer.

One or more embodiments of the present disclosure also provide a display panel which includes the above-mentioned array substrate.

### BRIEF DESCRIPTION OF THE DRAWINGS

FIG. 1 is a schematic diagram of a structure of an array substrate according to one or more embodiments of the present disclosure.

FIG. 2 is a cross-sectional view showing the connection between the first wiring segment and the second wiring segment in FIG. 1, according to one or more embodiments of the present disclosure.

FIG. 3 is a schematic diagram of another structure of an array substrate according to one or more embodiments of the present disclosure.

FIG. 4 is a cross-sectional view showing the connection between the first wiring segment and the second wiring segment in FIG. 3, according to one or more embodiments of the present disclosure.

FIG. 5 is a cross-sectional view showing the relative positions of the common electrode and the first wiring segment in an array substrate according to one or more embodiments of the present disclosure.

FIG. 6 is a schematic diagram of the structure of a display panel according to one or more embodiments of the present disclosure.

List of reference signs in the drawings:
10, display panel; 100, array substrate; S1, pixel area; S11, pixel sub-area; S2, driving area; S21, driving sub-area; 110, substrate layer; 120, first conductive layer; 121, first wiring segment; 122, gate; 123, scanning line; 130, first insulating layer; 131, first transfer hole; 140, second conductive layer; 141, second wiring segment; 142, source; 143, drain; 150, second insulating layer; 151, second transfer hole; 152, third transfer hole; 160, third conductive layer; 161, common electrode; 162, transfer electrode; 163, pixel electrode; 200, opposite substrate; X, first direction; Y, second direction; 300, liquid crystal layer; 310, liquid crystal molecules.

### DETAILED DESCRIPTION

The technical solution in the embodiments of the present disclosure will be clearly and completely described with reference to the accompanying drawings. It should be appreciated that the described embodiments are only some of the embodiments of the present disclosure, and not all of them. Based on the embodiments in the present disclosure, all other embodiments obtained by the skilled person in the art without involving any inventive effort fall within the scope of the present disclosure. Furthermore, it should be understood that the specific embodiments described herein are only for the purpose of illustration and explanation of the present disclosure, and are not intended to limit the present disclosure. In the present disclosure, unless otherwise specified, directional terms such as “up” and “down” generally refer to the direction of the device in its actual operation or working state, specifically the direction of the figure in the accompanying drawings; and “inside” and “outside” refer to the outline of the device.

One or more embodiments of the present disclosure provide an array substrate and a display panel, which will be described in detail below. It should be noted that the order of description of the following embodiments should not be deemed as limitation for the preferred order of the embodiments.

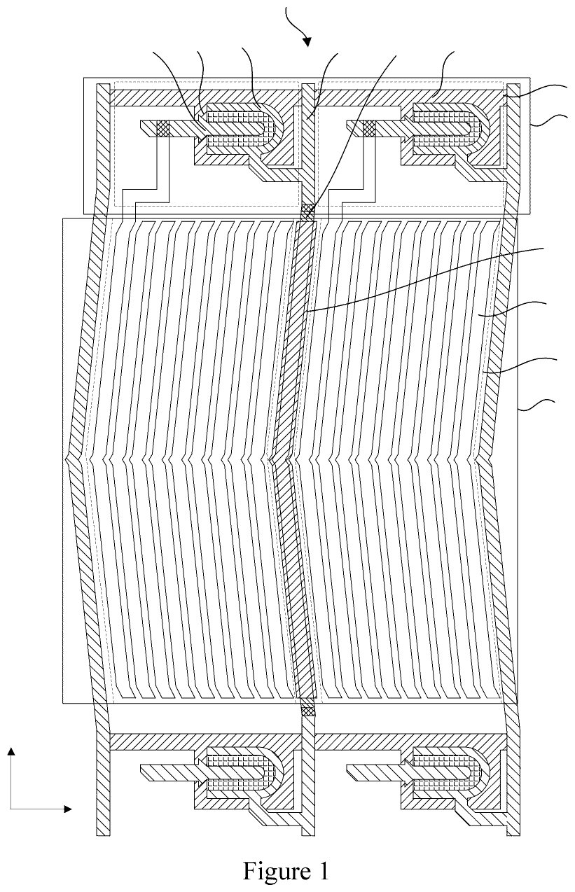

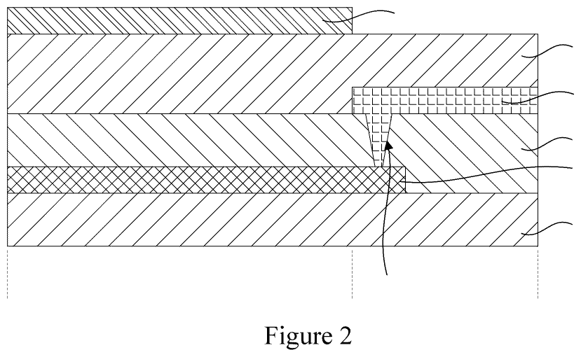

As shown in FIG. 1 and FIG. 2, an array substrate 100 includes a pixel area S1 and a driving area S2. The pixel area S1 is used to form light emitting pixels, and the driving area S2 is used to form a driving circuit, which receives control signals and controls the display of light emitting pixels in the pixel area S1.

The array substrate 100 includes a substrate layer 110, which serves as the base structure of the array substrate 100 and is used to support the subsequent functional film layers to ensure the overall structural stability of the array substrate 100. In some embodiments, the substrate layer 110 can be a rigid substrate or a flexible substrate made of glass or other materials, and there is no special limitation here.

The array substrate 100 includes a first conductive layer 120, a first insulating layer 130, a second conductive layer 140, a second insulating layer 150, and a third conductive layer 160 sequentially disposed on the substrate layer 110. The first insulating layer 130 is used to separate the first conductive layer 120 from the second conductive layer 140 to avoid interference between the first conductive layer 120 and the second conductive layer 140, which would affect the normal operation of the array substrate 100. The second insulating layer 150 is used to separate the second conductive layer 140 from the third conductive layer 160 to avoid interference between the second conductive layer 140 and the third conductive layer 160, which would affect the normal operation of the array substrate 100.

In some embodiments, the first conductive layer 120 includes a first wiring segment 121, which is at least partially located in the pixel area S1. The second conductive layer 140 includes a second wiring segment 141, which is at least partially located in the driving area S2. The second wiring segment 141 extends along a first direction X and is electrically connected to the first wiring segment 121. In other words, the integral structure formed by the second wiring segment 141 and the first wiring segment 121 extends from the driving area S2 to the pixel area S1, together forming a data line for receiving and transmitting data signals.

It should be noted that an extension trend of the first wiring segment 121 is consistent with that of the second wiring segment 141, that is, the overall extension trend of the first wiring segment 121 is still along the first direction X. However, according to the actual design requirements of the array substrate 100, the specific extension direction of the first wiring segment 121 may form a certain angle with the first direction X, and may even have a bending design in the extension direction to meet the different wiring requirements of the array substrate 100.

The third conductive layer 160 includes a common electrode 161 located in the pixel area S1. An extension direction of the common electrode 161 is consistent with that of the first wiring segment 121. An orthographic projection of the common electrode 161 on the substrate layer 110 at least partially overlaps an orthographic projection of the first wiring segment 121 on the substrate layer 110. That is, the common electrode 161 extends in the same direction as the first wiring segment 121 located in the pixel area S1, and in a thickness direction of the array substrate 100. The common electrode 161 is disposed above the first wiring segment 121.

It should be noted that the array substrate 100 is used to be disposed opposite to the opposite substrate 200 and assembled, and a liquid crystal layer 300 is filled between the array substrate 100 and the opposite substrate 200 to form the display panel 10. During the operation of the array substrate 100, the input signals of the common electrode 161 and of the opposite electrodes on the opposite substrate 200 are identical, so that the liquid crystal molecules 310 in the liquid crystal layer 300 above the common electrode 161 do not deflect, thereby avoiding the phenomenon of light leakage in the corresponding area of the first wiring segment 121 and playing a role in light shielding.

However, this configuration will lead to a significant increase in the capacitance of the data line, therefore resulting in a significantly larger parasitic capacitance of the corresponding pixel. The increase in parasitic capacitance will lead to a decrease in pixel charging rate and an increase in the risk of lateral crosstalk. One or more embodiments of the present disclosure place the first wiring segment 121 of the data line, which is positioned opposite to the common electrode 161, on the first conductive layer 120, so that the spacing between the common electrode 161 and the first wiring segment 121 changes from the thickness of the second insulating layer 150 to the sum of the thicknesses of the second insulating layer 150 and the first insulating layer 130, effectively increasing the thickness of the insulating layer between the common electrode 161 and the first wiring segment 121, thereby reducing parasitic capacitance, improving pixel charging rate, and decreasing the risk of crosstalk. In addition, since the second wiring segment 141 of the data line is still located in the second conductive layer 140, consistent with the original design, the wiring design of the driving circuit for the driving area S2 will not be affected while decreasing parasitic capacitance.

In one or more embodiments of the present disclosure, the array substrate 100 includes the pixel area S1 and the driving area S2, as well as the substrate layer 110, the first conductive layer 120, the first insulating layer 130, the second conductive layer 140, the second insulating layer 150, and the third conductive layer 160 arranged sequentially. The first conductive layer 120 includes the first wiring segment 121, which is at least partially located in the pixel area S1. The second conductive layer 140 includes the second wiring segment 141, which is at least partially located in the driving area S2. The second wiring segment 141 extends along the first direction X, and the second wiring segment 141 is electrically connected to the first wiring segment 121. The third conductive layer 160 includes the common electrode 161 located in the pixel area S1, and the extension direction of the common electrode 161 is consistent with that of the first wiring segment 121. The orthogonal projection of the common electrode 161 on the substrate layer 110 at least partially overlaps the orthogonal projection of the first wiring segment 121 on the substrate layer 110. One or more embodiments of the present disclosure place the first wiring segment 121 on the first conductive layer 120, so that the spacing between the common electrode 161 and the first wiring segment 121 changes from the thickness of the second insulating layer 150 to the sum of the thicknesses of the second insulating layer 150 and the first insulating layer 130, effectively increasing the thickness of the insulating layer between the common electrode 161 and the first wiring segment 121, thereby decreasing parasitic capacitance, improving pixel charging rate, and reducing the risk of crosstalk.

Optionally, as shown in FIG. 2, a first transfer hole 131 is formed in the first insulating layer 130, and the second wiring segment 141 is electrically connected to the first wiring segment 121 through the first transfer hole 131. Specifically, after the formation of the first insulating layer 130, the first insulating layer 130 is directly patterned and the first transfer hole 131 is formed on the first insulating layer 130. During the formation of the second wiring segment 141, an electrical connection to the first wiring segment 121 is realized directly through the first transfer hole 131. Since the second wiring segment 141 is separated from the first wiring segment 121 only by the first insulating layer 130, the electrical connection between the second wiring segment 141 and the first wiring segment 121 is simple and convenient.

In some embodiments, the first wiring segment 121 extends to the driving area S2, and the second wiring segment 141 is located in the driving area S2. An overlapping portion between the orthographic projection of the first wiring segment 121 on the substrate layer 110 and the orthographic projection of the second wiring segment 141 on the substrate layer 110 is located in the driving area S2. Specifically, the second wiring segment 141 is only located in the driving area S2, and the first transfer hole 131 is also located in the driving area S2. The first wiring segment 121 extends to the driving area S2 and is electrically connected to the second wiring segment 141. This design ensures that the portion of the data line corresponding to the common electrode 161 is entirely located in the first conductive layer 120, thereby ensuring sufficient spacing between the common electrode 161 and the corresponding portion of the data line, further decreasing parasitic capacitance, improving pixel charging rate, and reducing the risk of crosstalk risk.

In some embodiments, the first wiring segment 121 is located in the pixel area S1, and the second wiring segment 141 extends to the pixel area S1. An overlapping portion between the orthographic projection of the first wiring segment 121 on the substrate layer 110 and the orthographic projection of the second wiring segment 141 on the substrate layer 110 is located in the pixel area S1. Specifically, the first wiring segment 121 is only located in the pixel area S1, and the first transfer hole 131 is also located in the pixel area S1. The second wiring segment 141 extends to the pixel area S1 and is electrically connected to the first wiring segment 121. This design ensures that the connection area between the first wiring segment 121 and the second wiring segment 141 is located in the pixel area S1. In other words, the transition between the second wiring segment 141 and the first wiring segment 121 does not affect the wiring of the driving circuit in the driving area S2, thereby decreasing the impact on the driving area S2 and simplifying the structural design of the array substrate 100.

In other embodiments, the first wiring segment 121 extends to the driving area S2, the second wiring segment 141 extends to the pixel area S1, and the connection area between the first wiring segment 121 and the second wiring segment 141 is located at the junction of the driving area S2 and the pixel area S1. This design takes into consideration both the impact of parasitic capacitance and the impact on the wiring of the driving area S2.

It should be noted that the specific method for selecting the connection area between the first wiring segment 121 and the second wiring segment 141 can be adjusted according to the design requirements for decreasing parasitic capacitance and the wiring design of the driving area S2 during the actual design process, as long as the impact on the wiring of the driving area S2 is minimized while decreasing the parasitic capacitance, and there is no special limitation here.

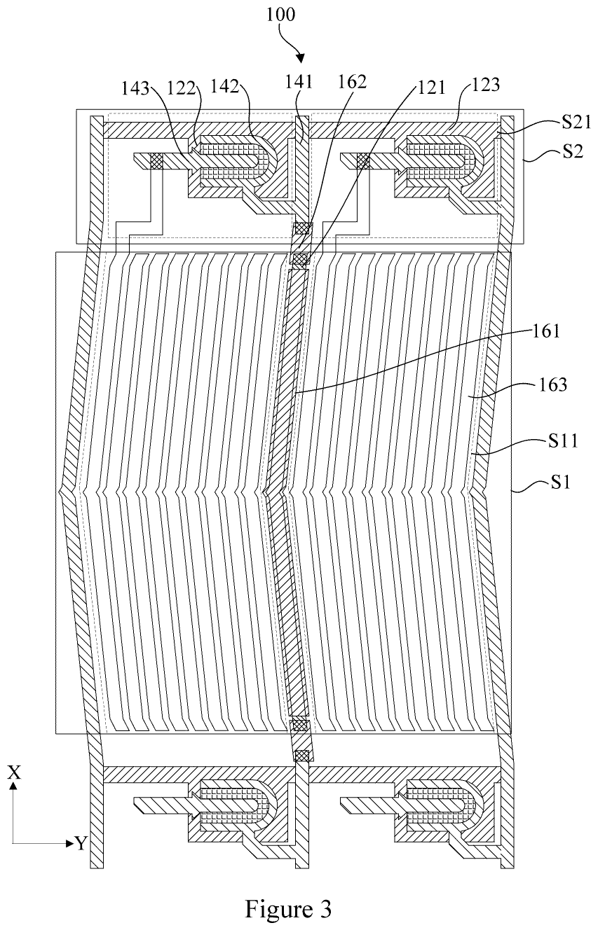

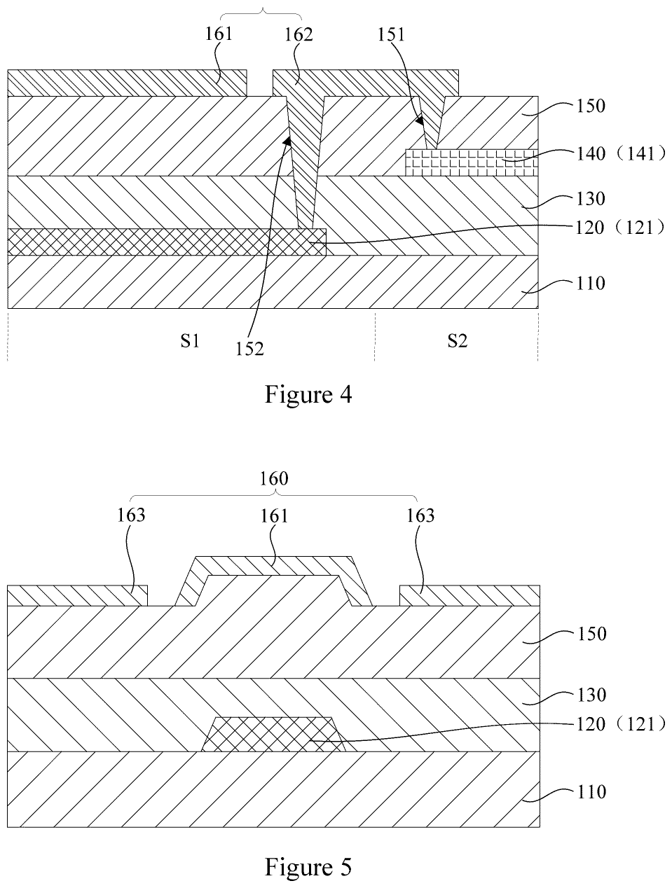

Optionally, as shown in FIG. 3 and FIG. 4, the third conductive layer 160 includes a transfer electrode 162, which is spaced apart from the common electrode 161. In other words, the transfer electrode 162 and the common electrode 161 are positioned on the same layer and patterned simultaneously using a photomask, and the transfer electrode 162 is insulated from the common electrode 161 to avoid mutual interference.

In an embodiment, a second transfer hole 151 and a third transfer hole 152 are formed in the second insulating layer 150. The third transfer hole 152 penetrates the first insulating layer 130. The second wiring segment 141 is electrically connected to the transfer electrode 162 through the second transfer hole 151, and the transfer electrode 162 is electrically connected to the first wiring segment 121 through the third transfer hole 152. Specifically, the second wiring segment 141 is connected to the first wiring segment 121 through the transfer electrode 162, which only serves as a function of transition. The transfer electrode 162, the first wiring segment 121, and the second wiring segment 141 together form the data line. This design allows the second transfer hole 151 and the third transfer hole 152 to be formed during the patterning process of the second insulating layer 150, without the need to add an additional photomask to form holes in the first insulating layer 130, thereby helping to decrease the number of photomasks used in the production process of the array substrate 100, improve production efficiency, and reduce production costs.

In some embodiments, the transfer electrode 162 extends from the pixel area S1 to the driving area S2, the first wiring segment 121 is located in the pixel area S1, and the second wiring segment 141 is located in the driving area S2. Specifically, the first wiring segment 121 is only located in the pixel area S1, the second wiring segment 141 is only located in the driving area S2, and the transfer electrode 162 is located both in the pixel area S1 and the driving area S2. The portion of the transfer electrode 162 located in the pixel area S1 is electrically connected to the first wiring segment 121 through the third transfer hole 152, and the portion of the transfer electrode 162 located in the driving area S2 is electrically connected to the second wiring segment 141 through the second transfer hole 151. This configuration ensures that when the data line is transferred from the second wiring segment 141 to the first wiring segment 121, the portion of the first wiring segment 121 corresponding to the common electrode 161 is entirely located in the pixel area S1, ensuring that the thickness of the insulating layer between the common electrode 161 and the first wiring segment 121 does not affect the wiring in the driving area S2, while the entire second wiring segment 141 is located in the driving area S2, thereby avoiding the increase in parasitic capacitance caused by the extension of the second wiring segment 141 to the driving area S2.

In other embodiments, as shown in FIG. 5, the spacing between the common electrode 161 and the first wiring segment 121 in the thickness direction of the array substrate 100 is greater than or equal to 5000 microns and less than or equal to 12000 microns. In other words, the thickness of the insulating layer between the common electrode 161 and the first wiring segment 121 is greater than or equal to 5000 microns and less than or equal to 12000 microns. If the spacing is too small, it will lead to the thickness between the common electrode 161 and the first wiring segment 121 being too small, and it will not be able to effectively decrease the parasitic capacitance. Conversely, if the spacing is too large, it will lead to the overall thickness of the array substrate 100 being too large, which is not conducive to lightweight and compact design.

In the practical manufacturing process, the spacing between the common electrode 161 and the first wiring segment 121 in the thickness direction of the array substrate 100 can be set to 5000 microns, 8000 microns, 10000 microns, or 12000 microns, etc. The specific value of spacing can be selected and adjusted according to actual design requirements, and there is no special limitation here.

Optionally, as shown in FIG. 1 and FIG. 3, the pixel area S1 includes a plurality of pixel sub-areas S11 distributed along a second direction Y, and the first wiring segment 121 and the common electrode 161 are formed between any two adjacent pixel sub-areas S11. The driving area S2 includes a plurality of sub driving areas S21 distributed along the second direction Y, and the second wiring segment 141 is formed between any two adjacent driving sub-areas S21. Specifically, in the thickness direction of the array substrate 100, the first wiring segment 121 and the common electrode 161 are located between adjacent pixel sub-areas S11, and the second wiring segment 141 is located between adjacent driving sub-areas S21 to avoid affecting the wiring of the driving sub-area S21, and the display of the pixel area S1.

In an embodiment, each pixel sub-area S11 is used to form a pixel, and each driving sub-area S21 is used to form a driving transistor. The second wiring segment 141 is electrically connected to the first wiring segment 121 respectively to form a plurality of data lines distributed along the second direction Y. The plurality of data lines are used to receive and transmit control signals to control the display of the plurality of pixel sub-areas S11. In an embodiment, the second direction Y forms an angle with the first direction X. In one or more embodiments of the present disclosure, the first direction X can be considered as the vertical (column) direction, and the second direction Y can be considered as the horizontal (row) direction. In other words, the second direction Y is perpendicular to the first direction X. The plurality of pixel sub-areas S11 and the plurality of driving sub-areas S21 are distributed in rows, and the overall arrangement is in an array, which facilitates the wiring design of the first wiring segment 121 and the second wiring segment 141, thereby decreasing parasitic capacitance, improving pixel charging rate, and reducing the risk of crosstalk, without significantly impacting the overall wiring design of the array substrate 100.

In some embodiments, the array substrate 100 includes a plurality of pixel areas S1 and a plurality driving areas S2, which are alternately arranged in the first direction X. Specifically, the plurality of pixel areas S1 and the plurality of driving areas S2 are arranged alternating in rows along the first direction X. In the first direction X, the first wiring segment 121 and the second wiring segment 141 are electrically connected alternately. Specifically, each data line is composed of the first wiring segments 121 and the second wiring segments 141, which are alternately electrically connected.

In an embodiment, each pixel area S1 includes a plurality of pixel sub-areas S11 distributed along the second direction Y, and each driving area S2 includes a plurality of driving sub-areas S21 distributed along the second direction Y. Specifically, pixel sub-areas S11 are distributed in an array, driving sub-areas S21 are distributed in an array, and the pixel sub-areas S11 and the driving sub-areas S21 are also distributed in an array as a whole, thereby decreasing parasitic capacitance, improving pixel charging rate, and reducing the risk of crosstalk, without significantly impacting the overall wiring design of the array substrate 100.

In some embodiments, the second conductive layer 140 further includes a source 142 and a drain 143 located in the driving sub-area S21, and the third conductive layer 160 further includes a pixel electrode 163 located in the pixel sub-area S11. The pixel electrode 163 is electrically connected to the drain 143, and the source 142 is electrically connected to the second wiring segment 141. Specifically, the second wiring segment 141 is used to receive data signals and transmit them to the pixel electrode 163 through the source 142 and drain 143 to control the display of the corresponding pixels. In an embodiment, the second wiring segment 141 located at the edge position receives the data signal, and then transmits the data signal along the first direction X through the first wiring segment 121 to the next second wiring segment 141, which then delivers it to the corresponding pixel electrode 163, thereby realizing the control of the inputting signals of the plurality of pixel electrodes 163 by one data line.

In an embodiment, the first conductive layer 120 also includes a gate 122 located in the driving area S2 and a scanning line 123. The scanning line 123 extends along the second direction Y, and one scanning line 123 penetrates the plurality of driving sub-areas S21 of one driving area S2. The scanning line 123 is used to receive scanning signals to control the display of the pixel area S1 together with the data signals. Each driving sub-area S21 is equipped with a gate 122, which is electrically connected to the scanning line 123, thereby realizing the control of one row of gates 122 by one scanning line 123.

In addition, an active layer is disposed between the first insulating layer 130 and the second conductive layer 140, and a channel area is formed on the active layer. The source 142 and the drain 143 are respectively connected to the two ends of the channel area on the active layer. The gate 122, the active layer, the source 142 and the drain 143 correspond to the driving transistor. After receiving the scanning signal, the scanning line 123 transmits the scanning signal to the gate 122, thereby making the channel area on the active layer conductive. After receiving the data signal, the data line transmits the data signal to the source 142, through the channel area on the active layer to the drain 143, and then delivers it to the pixel electrode 163, thereby realizing the connection and disconnection of the control signal on the pixel electrode 163.

It should be noted that, since the scanning line 123 and the first wiring segment 121 are disposed on the first conductive layer 120 respectively, the extension directions of the scanning line 123 and the first wiring segment 121 form an angle. For a data line, it can be considered as having an overall extending trend along the first direction X on the first conductive layer 120, and being disconnected at the position where it passes through the scanning line 123, thereby forming the plurality of first wiring segments 121. The adjacent two first wiring segments 121 are electrically connected by the second wiring segment 141 located in the second conductive layer 140, thus forming a complete data line.

Secondly, one or more embodiments of the present disclosure provide a display panel which includes an array substrate. The specific structure of the array substrate refers to the above-mentioned embodiments. Since this display panel adopts all the technical solutions of the above-mentioned embodiments, it at least has all the beneficial effects brought by the technical solutions of the above embodiments, which will not be elaborated here.

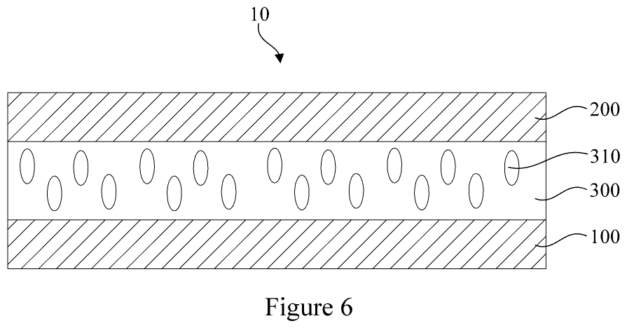

As shown in FIG. 6, the display panel 10 includes the array substrate 100, the opposite substrate 200, and the liquid crystal layer 300. The opposite substrate 200 is arranged opposite to the array substrate 100. When assembling the display panel 10, the array substrate 100 and the opposite substrate 200 are fastened together to form a containment cavity, and the liquid crystal layer 300 is filled in the containment cavity between the opposite substrate 200 and the array substrate 100. During the operation of the display panel 10, by regulating the driving signals on the array substrate 100, the liquid crystal molecules 310 in the liquid crystal layer 300 rotate to change the angle of the emitted light and form different display images.

Specifically, as shown in FIG. 1 and FIG. 2, the array substrate 100 includes the pixel area S1 and the driving area S2, as well as the substrate layer 110, the first conductive layer 120, the first insulating layer 130, the second conductive layer 140, the second insulating layer 150, and the third conductive layer 160 arranged sequentially. The first conductive layer 120 includes the first wiring segment 121, which is at least partially located in the pixel area S1. The second conductive layer 140 includes the second wiring segment 141, which is at least partially located in the driving area S2. The second wiring segment 141 extends along the first direction X, and the second wiring segment 141 is electrically connected to the first wiring segment 121. The third conductive layer 160 includes the common electrode 161 located in the pixel area S1. The extension direction of the common electrode 161 is consistent with that of the first wiring segment 121, and the orthographic projection of the common electrode 161 on the substrate layer 110 at least partially overlaps the orthographic projection of the first wiring segment 121 on the substrate layer 110. One or more embodiments of the present disclosure place the first wiring segment 121 on the first conductive layer 120, so that the spacing between the common electrode 161 and the first wiring segment 121 changes from the thickness of the second insulating layer 150 to the sum of the thicknesses of the second insulating layer 150 and the first insulating layer 130, effectively increasing the thickness of the insulating layer between the common electrode 161 and the first wiring segment 121, thereby decreasing parasitic capacitance, improving pixel charging rate, and reducing the risk of crosstalk.

Detailed introductions to the array substrate and the display panel according to one or more embodiments of the present disclosure are provided above. Specific examples are applied in this article to explain the principles and implementation methods of the present disclosure. The description of the above embodiments is only used to help understand the methods and core ideas of the present disclosure. Meanwhile, for skilled persons in the art, the specific implementation methods and scope of the disclosure may vary based on the ideas of the present disclosure. In summary, the content of this specification should not be understood as a limitation on the present disclosure.

What is claimed is:

1. An array substrate, comprising a pixel area and a driving area, the array substrate further comprising:
a substrate layer;
a first conductive layer disposed on the substrate layer, wherein the first conductive layer comprises a first wiring segment, which is at least partially located in the pixel area;
a first insulating layer disposed on the first conductive layer;
a second conductive layer disposed on the first insulating layer, wherein the second conductive layer comprises a second wiring segment, which is at least partially located in the driving area, the second wiring segment extends along a first direction and is electrically connected to the first wiring segment;
a second insulating layer disposed on the second conductive layer; and
a third conductive layer disposed on the second insulating layer, wherein the third conductive layer comprises a common electrode located in the pixel area, an extension direction of the common electrode is consistent with that of the first wiring segment, and an orthographic projection of the common electrode on the substrate layer at least partially overlaps an orthogonal projection of the first wiring segment on the substrate layer.

2. The array substrate of claim 1, wherein a first transfer hole is formed in the first insulating layer, and the second wiring segment is electrically connected to the first wiring segment through the first transfer hole.

3. The array substrate of claim 2, wherein the first wiring segment extends to the driving area, the second wiring segment is located in the driving area, and an overlapping portion between the orthographic projection of the first wiring segment on the substrate layer and the orthographic projection of the second wiring segment on the substrate layer is located in the driving area.

4. The array substrate of claim 1, wherein the third conductive layer comprises a transfer electrode, which is spaced apart from the common electrode; and wherein a second transfer hole and a third transfer hole are formed in the second insulating layer, the third transfer hole penetrates the first insulating layer, the second wiring segment is electrically connected to the transfer electrode through the second transfer hole, and the transfer electrode is electrically connected to the first wiring segment through the third transfer hole.

5. The array substrate of claim 4, wherein the transfer electrode extends from the pixel area to the driving area, the first wiring segment is located in the pixel area, and the second wiring segment is located in the driving area.

6. The array substrate of claim 1, wherein the spacing between the common electrode and the first wiring segment in a thickness direction of the array substrate is greater than or equal to 5000 microns and less than or equal to 12000 microns.

7. The array substrate of claim 1, wherein the pixel area comprises a plurality of pixel sub-areas distributed along a second direction, the first wiring segment and the common electrode are formed between any two adjacent pixel sub-areas; the driving area comprises a plurality of driving sub-areas distributed along the second direction, the second wiring segment is formed between any two adjacent driving sub-areas; the second wiring segment is electrically connected to the first wiring segment respectively; and the second direction forms an angle with the first direction.

8. The array substrate of claim 7, wherein the array substrate comprises a plurality of pixel areas and a plurality of driving areas, the plurality of pixel areas and the plurality of driving areas are alternately arranged in the first direction; and in the first direction, the first wiring segment and the second wiring segment are electrically connected alternately.

9. The array substrate of claim 7, wherein the second conductive layer further comprises a source and a drain located in the driving sub-area, and the third conductive layer further comprises a pixel electrode located in the pixel sub-area, wherein the pixel electrode is electrically connected to the drain, and the source is electrically connected to the second wiring segment.

10. A display panel, comprising an array substrate, wherein the array substrate comprises a pixel area and a driving area, and the array substrate further comprises:
a substrate layer;
a first conductive layer disposed on the substrate layer, wherein the first conductive layer comprises a first wiring segment, which is at least partially located in the pixel area;
a first insulating layer disposed on the first conductive layer;
a second conductive layer disposed on the first insulating layer, wherein the second conductive layer comprises a second wiring segment, which is at least partially located in the driving area, and the second wiring segment extends along a first direction and is electrically connected to the first wiring segment;
a second insulating layer disposed on the second conductive layer; and
a third conductive layer disposed on the second insulating layer, wherein the third conductive layer comprises a common electrode located in the pixel area, an extension direction of the common electrode is consistent with that of the first wiring segment, and an orthographic projection of the common electrode on the substrate layer at least partially overlaps an orthogonal projection of the first wiring segment on the substrate layer.
